(19) United States
(12) Patent Application Publication
(10) Pub. No.: US 2013/0193470 A1
(43) Pub. Date: Aug. 1, 2013

(54) Optoelectronic Component and Method for Producing an Optoelectronic Component

(71) Applicants: Karl Weidner, Muenchen (DE); Johann Ramchen, Altdorf (DE); Axel Kaltenbacher, Mintraching (DE); Walter Wegleiter, Nittendorf (DE); Bernd Barchmann, Regensburg (DE); Gertrud Kraeuter, Regensburg (DE)

(72) Inventors: Karl Weidner, Muenchen (DE); Johann Ramchen, Altdorf (DE); Axel Kaltenbacher, Mintraching (DE); Walter Wegleiter, Nittendorf (DE); Bernd Barchmann, Regensburg (DE); Gertrud Kraeuter, Regensburg (DE)

(73) Assignee: OSRAM OPTO SEMICONDUCTORS GMBH, Regensburg (DE)

(21) Appl. No.: 13/816,196

(22) PCT Filed: Aug. 10, 2011
(86) PCT No.: PCT/EP2011/063788

§ 371 Date: Apr. 17, 2013

(30) Foreign Application Priority Data
Aug. 11, 2010 (DE) 10 2010 033 963.6

(51) Int. Cl. H01L 33/44; H01L 33/00

(52) U.S. Cl. CPC H01L 33/44; H01L 33/0095
USPC 257/98; 438/38

(57) ABSTRACT

An optoelectronic component includes a protective layer including a material containing hydrophobic groups. Furthermore, a method is described, by means of which an optoelectronic component can be produced, and in which a protective layer including hydrophobic groups is applied.

This patent application is a national phase filing under section 371 of PCT/EP2011/063788, filed Aug. 10, 2011, which claims the priority of German patent application 10 2010 033 963.6, filed Aug. 11, 2010, each of which is incorporated herein by reference in its entirety.

### TECHNICAL FIELD

An optoelectronic component having a protective layer is described as well as a method for producing an optoelectronic component, in which a protective layer is applied.

### BACKGROUND

Semiconductor chips, for example light-emitting diode (LED) chips, can have reduced performance caused by contamination of the surface of the semiconductor chip. Thus for example a portion of the light produced in an LED chip can be lost owing to the absorption of the emitted light by contamination on the surface of the chip.

Absorption losses brought about by constructional factors in the formation of an LED component can be reduced, for example, by application of a reflective coating on the substrate of an LED chip. Absorption losses through the substrate can thereby be reduced. This feature can be further optimized by a flat filling reaching as far as the upper edge of the chip, or a filler or by embedding the chip in highly reflective filler material, for example TiO₂-filled silicone. A problem with this feature is contamination of the chip surface by the filler material running over or by splashing during processing.

### SUMMARY OF THE INVENTION

One embodiment of the invention provides a component that is largely free of contamination on the chip surface and therefore offers better performance. A further embodiment provides a method with which a component containing a semiconductor chip, the surface of which is free of contamination, is provided.

An optoelectronic component is described which includes a substrate, at least one radiation-emitting semiconductor chip, which is disposed on the substrate, and a filler which is disposed on the substrate laterally enclosing the semiconductor chip. The diameter of the substrate can therefore be larger than the diameter of the semiconductor chip, which means that the filler can be disposed on the substrate and around the semiconductor chip. Filler material can include for example silicone which is filled with TiO₂.

The optoelectronic component can furthermore have a protective layer which is disposed over the whole surface or partial regions on the semiconductor chip and has an outer surface facing away from the semiconductor chip. The protective layer can comprise a material which contains hydrophobic groups which, being disposed on the surface of the chip, ensure that the surface is not wetted.

“Over the whole surface” means in this context that the protective layer completely covers the semiconductor layer on the side facing away from the substrate and not enclosed by the filler. “Partial regions” consequently means that there is not complete, but only partial, covering of the semiconductor chip by the protective layer on the side facing away from the substrate and not enclosed by the filler.

Furthermore the component can have a first and a second contact which are connected in an electrically conductive manner to the semiconductor chip. The filler and the semiconductor chip can be disposed inside a housing.

The arrangement of the protective layer “on” the semiconductor chip means that the protective layer is disposed on the side of the semiconductor chip facing away from the substrate. This arrangement can be produced directly on the semiconductor chip. However, the expression “on” also includes the arrangement of the protective layer on a further layer or layer sequence which for its part can be disposed on the side of the semiconductor chip facing away from the substrate. A further layer of this type can include, for example, a radiation-conversion layer.

The following statements relating to the protective layer, which is disposed on the side of the semiconductor chip facing away from the substrate, also relate to sides of other layers or layer sequences facing away from the substrate, which layers or layer sequences can be provided between the semiconductor chip and the protective layer even if these layers or layer sequences are not explicitly mentioned.

The protective layer makes it possible to provide a filler laterally enclosing the semiconductor chip and able to be formed in a highly reflective manner for radiation emitted by the semiconductor chip, without the surface of the semiconductor chip being contaminated by filler material. Contamination is prevented by the fact that the protective layer is provided over the whole surface or in partial regions on the semiconductor chip. Partial regions preferably include the edges, adjoining the filler, of the side of the semiconductor chip facing away from the substrate.

Therefore, on the one hand, the absorption of radiation emitted by the semiconductor chip by the substrate is prevented by the presence of the highly reflective filler, on the other hand, absorption owing to contamination of the semiconductor chip surface with filler material is avoided. The component can thus have optimal decoupling efficiency and reduced absorption losses.

Hydrophobic groups can each contain at least one perfluorinated carbon. The hydrophobic groups can be contained in a chain-like molecule. For example, the material of the protective layer can comprise substituted or unsubstituted hydrocarbon chains, at one end of which a CF₃ group is provided.

The material of the protective layer can furthermore contain silane groups which can be functionalized. These can be provided at the end of a molecule chain, for example of a hydrocarbon chain on which the CF₃ group is not provided. A functionalized silane group can be bonded by a covalent bond with the semiconductor chip surface or the surface of other layers or layer sequences which can be provided on the semiconductor chip, and it can therefore attach the protective layer to the semiconductor chip or to other layers. If no silane group is provided, the attachment of the protective layer to the semiconductor chip or to other layers can also be brought about by hydrogen bridge bonds or Van-der-Waals interactions.

The material of the protective layer is thus at least partially PTFE-like, that is to say it contains polytetrafluoroethylene (PTFE)-like fluorohydrocarbons which can contain CF₃ groups, whereby the hydrophobic property is achieved.

The protective layer can have a thickness which is selected from the range of 1 to 10 nm. The protective layer can be provided in one or a plurality of monolayers. One or a few monolayers of the material of the protective layer contain sufficient free volume to permit the hydrophobic groups to move within the material.

The hydrophobic groups can be provided on the outer surface of the protective layer. The protective layer may not be wettable. If the hydrophobic groups are provided on the outer surface of the protective layer, they bring about the non-wettability of the protective layer which thus acts in a repellent manner with respect to other materials.

The non-wettability of the protective layer is also provided with respect to the filler material which is usefully applied only after the protective layer is disposed on the semiconductor chip. There is therefore no, or at least reduced, wetting of the side of the semiconductor chip facing away from the substrate with filler material and contamination of the semiconductor chip with filler material is prevented or reduced. The non-wettability of the protective layer is made possible by the hydrophobic groups and low surface energy thereby achieved.

The outer surface of the protective layer can furthermore be at least partially free of hydrophobic groups. The protective layer can then be wettable. “Free” means in this context that hydrophobic groups are at least partially folded into the inside of the protective layer by a brief thermal treatment, whereby the wettability of the surface increases. Thus, for example, materials with relatively low surface tension, such as silicones, can be applied without leading to delamination.

If the outer surface of the protective layer is at least partially free of hydrophobic groups, these can be provided within the protective layer or at the boundary surface between the protective layer and the semiconductor chip or between the protective layer and a layer or layer sequence applied to the semiconductor chip.

The outer surface of the protective layer is therefore wettable, whereby further layers and/or elements of the component, for example a lens, can be applied to the protective layer. Further layers, which are applied, can include conversion layers and layers to provide protection against environmental or mechanical influences. Furthermore, by reason of the wettability of the protective layer, the hydrophobic groups of which are not provided on the outer surface of the protective layer, delamination of the further layers and/or elements of the component applied to the protective layer can be prevented.

The semiconductor chip can include an LED chip. The optoelectronic component is then an LED component which can serve to emit visible light.

Furthermore, between the semiconductor chip, for example the LED chip, and the protective layer a conversion layer can be provided. The conversion layer can convert light of a first wavelength, which is emitted by the semiconductor chip, for example an LED chip, into a second wavelength different from the first and can therefore change the overall impression of color given by the emitted light of the component. The conversion layer can include, for example, a chip-level-conversion (CLC) layer.

The protective layer can be formed in such a way that it is releasable. For example, it can be soluble in a solvent or can be sensitive with respect to plasma treatments. The protective layer can, for example, be released after the filler material has been applied and contamination by filler material can no longer arise. Application of further layers and/or further elements of the component directly to the semiconductor chip or even to a layer, for example a conversion layer provided on the semiconductor chip, therefore becomes possible.

Furthermore, a method for producing an optoelectronic component is described. The method can the method steps: A) provision of a radiation-emitting semiconductor chip which is disposed on a substrate, B) application of a protective layer to the semiconductor chip, wherein the protective layer has an outer surface facing away from the semiconductor chip and has hydrophobic groups at least on the outer surface, C) application of a filler to the substrate, which laterally encloses the semiconductor chip, and D) removing the hydrophobic groups from the outer surface of the protective layer or from the component.

By application of the protective layer, which has hydrophobic groups on its outer surface, in method step B) a non-wettable protective layer is applied before, in method step C), a filler is applied, laterally of the semiconductor chip, to the substrate, which favorably has a larger diameter than the semiconductor chip. Therefore contamination of the semiconductor chip by the non-wettable protective layer is prevented since any splashes of the filler material or overrunning of the filler material beyond the semiconductor chip does not cause any wetting of the semiconductor chip with filler material.

This is made possible both by application of the protective layer to the whole surface of the semiconductor chip and also to partial regions, for example edge regions of the side of the semiconductor chip facing away from the substrate.

By removing the hydrophobic groups in method step D) the protective layer becomes wettable, whereby further layers and/or further elements of the component can be applied to the semiconductor chip. Further layers can include a conversion layer or layers for protection against environmental or mechanical influences. Further elements of the component can include, for example, a lens. Before application of a protective layer in method step B) a conversion layer can also be applied to the semiconductor chip in a method step A1). The protective layer is then applied to the conversion layer and therefore protects the conversion layer against possible contamination with filler material.

With this method a protective layer with reversible non-wettability is thus applied, thus rendering possible uncomplicated application of further layers and/or elements and simultaneous protection against contamination with filler material. The non-wettability of the protective layer prevents or reduces contamination with filler material, whereby absorption losses in the emitted radiation of the semiconductor chip can be avoided. In this way the application of the filler material is more robust and quicker, which can result in lower process costs.

The removal of the hydrophobic groups in method step D) can be achieved by releasing the protective layer from the semiconductor chip. If a conversion layer is provided on the semiconductor chip, the protective layer can be released from the conversion layer.

Release in method step D) can be effected, for example, by a plasma treatment or by a chemical treatment. A plasma treatment can be carried out, for example, by means of a CF₄ or an SF₆ plasma or by an REE (reactive ion) plasma. A chemical release can be carried out, for example, by solvent, for example fluorinated hydrocarbons. Release of the protective layer means that the non-wettability of the protective layer does not have to be made reversible in order to be able to apply further layers and/or elements of the component. Release is carried out only after the filler material has been applied laterally of the semiconductor chip, so that contamination of the semiconductor chip with filler material can be effectively prevented.

The removal of the hydrophobic groups in method step D) can be effected by heating the protective layer to a temperature selected from the range 160° C. to 170° C. The semiconductor chip and the substrate can thereby also be heated. The heating can be carried out for a short time, for example a few minutes.

During heating, the hydrophobic groups can be at least partially folded from the outer surface of the protective layer in the direction of the inside of the protective layer. The hydrophobic groups can thus fold into the inside of the protective layer and/or to the boundary surface of the protective layer with the semiconductor chip or the boundary surface of the protective layer with a layer which is disposed on the semiconductor chip.

If a conversion layer is provided on the semiconductor chip, the hydrophobic groups are folded into the inside of the protective layer and/or to the boundary surface of the protective layer with the conversion layer. On the outer surface of the protective layer organic residues remain in both cases, which produce the wettability of the protective layer. The inwards folding is effected by molecular movements made possible by mobility of the chain. The hydrophobic groups fold at least partially inwards. Even if not all hydrophobic groups are folded inwards, the wettability of the surface can be increased sufficiently that further layers can be applied to the surface.

The hydrophobic groups can be contained in chain-like molecules and include, for example, perfluorinated hydrocarbons as described above for the protective layer of the optoelectronic component. The folding of hydrophobic groups can be effected by folding-in or folding of the chain-like molecules of the material of the protective layer.

Therefore further layers and/or elements of the component can be applied to the protective layer which has been rendered wettable, and delamination of these layers or elements can be avoided.

Subsequent processes after application of the filler can thus take place with the protective layer remaining on the semiconductor chip since the wettability thereof has been achieved.

The protective layer can have a thickness selected from the range of 1 to 10 nm. This thickness can correspond to one or a few monolayers of the material of the protective layer. One or a few monolayers of the material of the protective layer contain sufficient free volume to permit the mobility of the hydrophobic groups within the material. The folded-in hydrophobic groups can no longer be folded back onto the outer surface of the protective layer even after cooling of the protective layer or of the component. The wettability of the protective layer is therefore stabilized.

The protective layer can be applied in method step B) by a method selected from a group including jetting, spraying and stamping. By jetting or stamping the protective layer can be applied in a targeted manner, for example in only partial regions of the surface of the semiconductor chip. Therefore, the protective layer can be applied, for example, only at the edge of the side of the semiconductor chip facing away from the substrate, whereby the majority of the chip surface remains free of protective layer. Wetting of the chip surface by filler material, for example silicone filled with TiO₂, is prevented.

A method is thus provided, in which the protective layer can be applied completely, i.e., over the whole surface, or to partial regions of the semiconductor chip.

After application of the filler material which laterally encloses the semiconductor chip, the protective layer can either be removed or be rendered wettable by a temperature treatment. Therefore semiconductor chips can be enclosed up to their upper edge by highly reflective filler material by means of a robust and inexpensive method, which leads to optimized decoupling efficiency. The contamination of the semiconductor chip or possibly of the conversion layer on the semiconductor chip with highly reflective filler material is prevented, whereby no, or reduced, absorption losses occur.

### BRIEF DESCRIPTION OF THE DRAWINGS

Some embodiments of the invention are explained in more detail hereinunder with the aid of the description of the figures in which:

FIG. 1 shows a schematic side view of an optoelectronic component;

FIG. 2 shows a schematic side view of an alternative embodiment of an optoelectronic component; and

FIG. 3 shows a schematic side view of a protective layer.

### DETAILED DESCRIPTION OF ILLUSTRATIVE EMBODIMENTS

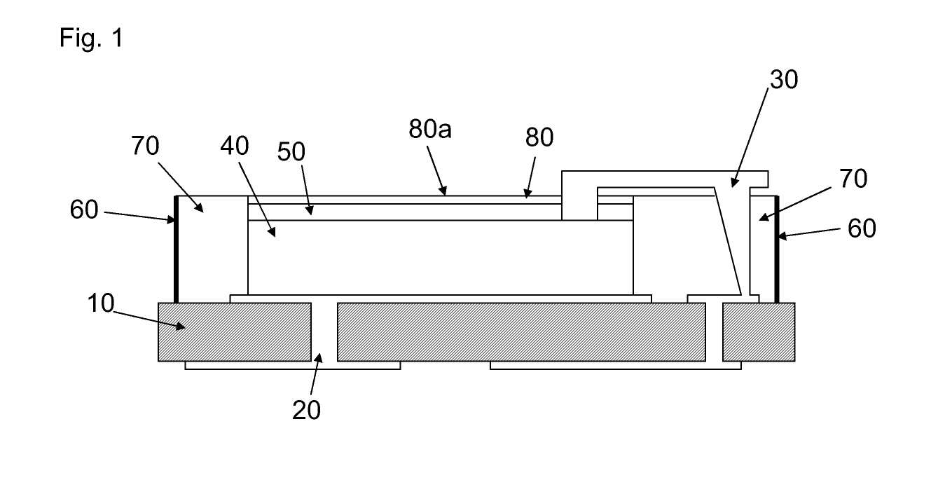

FIG. 1 shows the schematic side view of an optoelectronic component using the example of an LED component. The component includes the substrate 10, which has two interlayer connections through which the first contact 20 and the second contact 30 are passed. With the two contacts, the electrical contact between two sides of the semiconductor chip 40, in this example, an LED chip, is possible.

The semiconductor chip 40 is laterally enclosed by a filler 70. The filler 70 can optionally be located inside a housing 60. A conversion layer 50 can be disposed on the semiconductor chip 40. The conversion layer 50 has a side facing away from the substrate, on which the protective layer 80 is disposed. Arrangement, not shown here, of the protective layer 80 directly on the semiconductor chip 40 is also possible.

The protective layer 80 contains hydrophobic groups which are provided on the outer surface 80a of the protective layer 80 during application of the protective layer 80. The protective layer is therefore not wettable and therefore prevents contamination of the semiconductor chip 40 with filler material when the filler 70 is applied after application of the protective layer 80. The filler 70 can include a highly reflective material, for example a silicone which contains TiO₂ particles.

The substrate 10 has a larger surface than the semiconductor chip 40, which means that the filler 70 can be applied around the semiconductor chip on the substrate. After application of the filler 70, the protective layer 80 can be treated in such a way that there are at least partially no hydrophobic groups remaining on the outer surface 80a of the protective layer. Therefore the protective layer 80 is wettable, which means that further layers and/or elements, such as for example a lens, can be applied.

The hydrophobic groups of the protective layer include PFTE-like compounds, for example perfluorinated hydrocarbons. The bonding of the protective layer 80 to the surface of the semiconductor chip or of the conversion layer is effected covalently, by hydrogen bridge bonds or Van-der-Waals interactions.

The first and the second contact shown here are CPHF contacts (CPHF: compact planar high flux). Alternative contacts, for example by means of bond wire, not shown here, are also feasible.

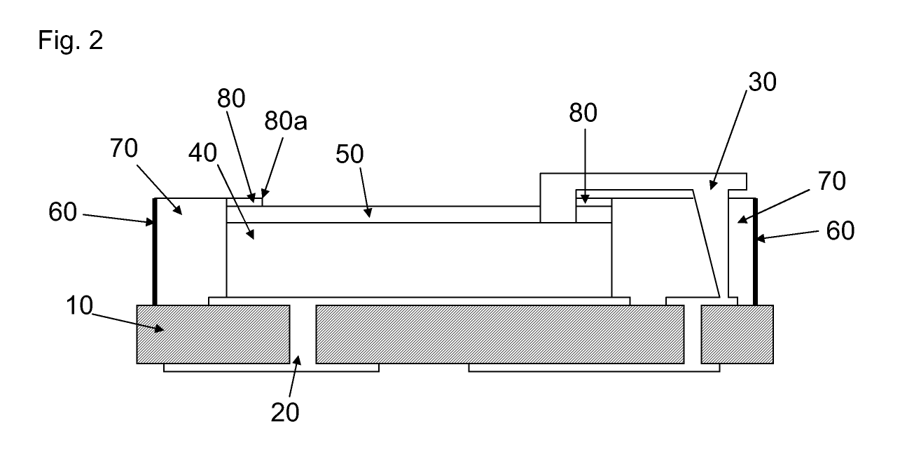

FIG. 2 shows a further embodiment of an optoelectronic component. All reference numerals are to be understood as in FIG. 1. In this case the protective layer 80 is applied only in edge regions of the surface of the semiconductor chip 40. This can take place, for example, by jetting or stamping of the material of the protective layer 80. In this embodiment a large part of the surface of the semiconductor chip 40 or of the conversion layer 50 remains free of material of the protective layer. Nevertheless, owing to the non-wettability of the protective layer 80 contamination of the semiconductor chip 40 or of the conversion layer 50 by filler material, which splashes or runs over the edge of the semiconductor chip 40 during application, is prevented.

If the conversion layer 50 is not provided on the semiconductor chip 40, it can be applied to the protective layer 80 as soon as this has been rendered wettable by a temperature treatment.

After the filler 70 has been applied, the protective layer 80 of FIG. 1 or 2 can alternatively also be released (not shown here). Release can be effected, for example, by a plasma or by a chemical treatment, for example by means of a solvent. After release of the protective layer 80 further layers and/or elements of the component (not shown here) can be applied to the surface of the semiconductor chip 40 or of the conversion layer 50. Such layers include conversion layers or layers for protection against mechanical or environmental influences. An element which could still be applied would be, for example, a lens (not shown here).

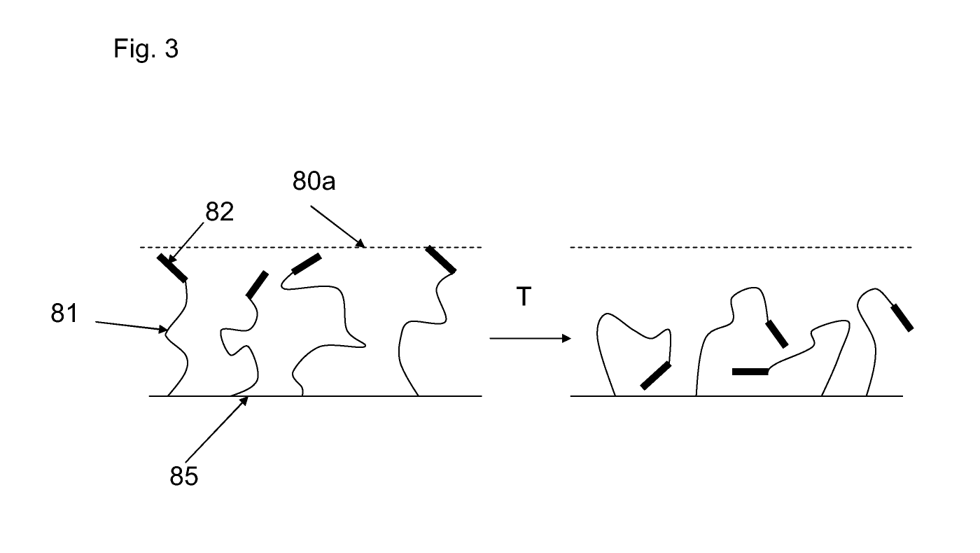

FIG. 3 shows a schematic side view of a protective layer 80. This contains chain-like molecules 81 and hydrophobic groups 82, which are disposed on the left side of FIG. 3 all on the outer surface 80a (indicated by the broken line) of the protective layer 80. The protective layer is located on a surface 85. Owing to the temperature effect T the hydrophobic groups 82 can fold at least partially into the inside of the protective layer 80, whereby the outer surface 80a is substantially free of hydrophobic groups and is therefore wettable.

The invention is not limited to the exemplified embodiments shown herein but rather allows further embodiments and combinations thereof.

1-15. (canceled)

16. An optoelectronic component, comprising:
a substrate;
a radiation-emitting semiconductor chip disposed on the substrate;
a filler disposed on the substrate laterally surrounding the semiconductor chip; and
a protective layer disposed completely or in partial regions on the semiconductor chip and having an outer surface facing away from the semiconductor chip, wherein the protective layer includes a material that contains hydrophobic groups.

17. The optoelectronic component according to claim 16, wherein the hydrophobic groups each contain at least one perfluorinated carbon.

18. The optoelectronic component according to claim 16, wherein the protective layer has a thickness between 1 and 10 nm.

19. The optoelectronic component according to claim 16, wherein the hydrophobic groups are provided on an outer surface of the protective layer and the protective layer is non-wettable.

20. The optoelectronic component according to claim 16, wherein the outer surface of the protective layer is at least partially free of hydrophobic groups and the protective layer is wettable.

21. The optoelectronic component according to claim 16, wherein the semiconductor chip comprises an LED chip.

22. The optoelectronic component according to claim 21, further comprsing a conversion layer between the LED chip and the protective layer.

23. The optoelectronic component according to claim 16, wherein the protective layer is releasable.

24. A method for producing an optoelectronic component, the method comprising:
A) providing a radiation-emitting semiconductor chip disposed on a substrate,
B) applying a protective layer to the semiconductor chip, wherein the protective layer has an outer surface facing away from the semiconductor chip and hydrophobic groups at least on the outer surface,
C) applying a filler to the substrate, so that the filler laterally surrounds the semiconductor chip, and
D) removing the hydrophobic groups from the outer surface of the protective layer or from the component.

25. The method according to claim 24, wherein the hydrophobic groups are removed by releasing the protective layer from the semiconductor chip.

26. The method according to claim 25, wherein the protective layer is released by a plasma treatment or by a chemical treatment.

27. The method according to claim 24, wherein removing the hydrophobic groups comprises heating the protective layer to a temperature in the range 160° C. to 170° C.

28. The method according to claim 27, wherein the hydrophobic groups fold from the outer surface of the protective layer in the direction of the inside of the protective layer.

29. The method according to claim 24, wherein the protective layer is applied by jetting, spraying or stamping.

30. The method according to claim 24, wherein the protective layer is applied to partial regions or to the whole surface of the semiconductor chip.

31. An optoelectronic component, comprising:
a substrate;
a radiation-emitting semiconductor chip disposed on the substrate;
a filler disposed on the substrate laterally surrounding the semiconductor chip; and
a protective layer disposed completely or in partial regions on the semiconductor chip and having an outer surface facing away from the semiconductor chip;
wherein the protective layer includes at least one monolayer of a material that contains hydrophobic groups; and
wherein an outer surface of the protective layer facing away from the semiconductor chip has a hydrophobicity, wherein the hydrophobicity are reducible by moving the hydrophobic groups within the material.
